(19) United States
(12) Patent Application Publication
(10) Pub. No.: US 2005/0158671 A1
(43) Pub. Date: Jul. 21, 2005

(54) Method for manufacturing a semiconductor device and a cleaning device for stripping resist

(76) Inventors: Yuji Shimizu, Kanagawa (JP); Tatsuya Suzuki, Kanagawa (JP); Michihisa Kohno, Kanagawa (JP)

Correspondence Address: YOUNG & THOMPSON, 745 SOUTH 23RD STREET, 2ND FLOOR, ARLINGTON, VA, 22202, US

(21) Appl. No.: 10/995,823

(22) Filed: Nov. 24, 2004

(30) Foreign Application Priority Data
Nov. 25, 2003 (JP) 2003-394249
Nov. 9, 2004 (JP) 2004-324601

(51) Int. Cl. G03F 7/00; G03F 7/42

(52) U.S. Cl. 430/329; 430/313

(57) ABSTRACT

A method for manufacturing a semiconductor device and a cleaning device for stripping resist provide semiconductor device with superior element characteristic in a sufficient yield, in such away that, after dry etching of the lithography process, wet cleaning removes resists, and particles or metal impurities are made to sufficiently remove without damaging fine pattern. The method for manufacturing the semiconductor device comprises: forming a resist pattern on a film provided for the semiconductor substrate, forming a fine pattern of conductive film while performing dry etching using the resist pattern as a mask, stripping the resist pattern by single-wafer system treatment upon supplying resist stripping liquid to fine pattern forming surface of the semiconductor substrate, and carrying out rinse treatment of the semiconductor substrate.

This application is based on Japanese patent applications NO.2003-394249 and NO.2004-324601, the contents of which are incorporated herein by reference.

### BACKGROUND OF THE INVENTION

1. Field of the Invention

The present invention relates to a method for manufacturing a semiconductor device and a cleaning device stripping resist using the same method.

2. Related Art

Conventionally, in the manufacturing of the semiconductor device, a fine pattern formation of a gate electrode or the like is carried out in such a way that a resist film is formed on a conductive film provided on a semiconductor substrate, followed by carrying out dry etching with a resist pattern of the resist film obtained by patterning it as a mask, and the conductive film is subjected to patterning into predetermined size and shape. And, as one technique of resist stripping after the patterning, carried out is a so-called SPM cleaning using mixed solution of sulfuric acid and hydrogen peroxide, subsequently, rinse treatment with pure water is performed.

This SPM cleaning, conventionally, has been performed in such a way that SPM is filled on the inside of treatment tank made of acid/thermal-resistant material such as quartz or the like, followed by being kept the SPM into predetermined temperature, thereafter, wafer is immersed in the SPM, it is so-called a dip type treatment. After the SPM cleaning, the wafers are immersed in a treatment tank filled with pure water, followed by performing dip type rinse treatment, and finally, drying treatment of wafer is performed.

As a dip type cleaning method, for instance, the Japanese Laid-Open Patent Publication No. HEI 09-017763 has disclosed the batch processing according to the cassette system, which performs cleaning while inserting the cassettes in which plural sheets of wafers are accommodated, into the treatment tank, and the batch processing according to the cassetteless system without using the cassette in which plural sheets of wafers are processed simultaneously.

On the other hand, the Japanese Laid-Open Patent Publication No. HEI 05-121388 has disclosed so-called cleaning method of a single-wafer-type treating system in which wafer is treated one-by-one as an object to solve such a problem or the like that, in batch type cleaning treatment of dip system, control of cleaning condition becomes difficult because of increasing the size of the treatment tank.

The dip system performs treatment while immersing a plurality of wafers in the treatment tank. This system has the advantage capable of treating a plurality of wafers at one time, however, a plurality of wafers are made to immerse into treatment solution side by side, for this reason, contaminants removed from reverse side of the wafer are dissolved or dispersed into aqueous solution, after that, in some cases, re-attachment of the contaminants to the surface of neighboring another wafer takes place. On the other hand, the single-wafer type system is a system carrying out treatment of wafer one by one, in such a treatment that the wafer is horizontally fixed on a holding table, and treatment is carried out upon spraying treating liquid to its surface while being made to rotate in a wafer plane. According to this system, problem of contaminants caused by another wafer is not generated, thus it becomes possible to carry out treatment with high cleanliness.

In the manufacturing process of the semiconductor device, wet treatment using treatment liquid such as cleaning, etching, separation of resist layer and the like are frequently performed. As an device performing such wet treatment, there are dip system one and single-wafer type one in a roughly dividing manner. The dip system is one that performs treatment while immersing a plurality of wafers into the treatment tank. This system, described above, has the advantage capable of treating a plurality of wafers at one time, however, a plurality of wafers are made to immerse into treatment solution side by side, for this reason, contaminants removed from reverse surface of the wafer are dissolved or dispersed into aqueous solution, after that, in some cases, re-attachment of the contaminants to the surface side of neighboring another wafer takes place. On the other hand, the single-wafer type system is a system carrying out treatment of wafer one by one, in such a treatment that the wafer is horizontally fixed on a holding table, and treatment is carried out upon spraying treating liquid to its surface while being made to rotate in a wafer plane. According to this system, problem of contaminants caused by another wafer is not generated, thus it becomes possible to carryout treatment with high cleanliness.

The Japanese Laid-Open Patent Publication No. HEI 06-291098 describes a single-wafer type substrate cleaning device. This device effectively uses the heat of mixing generated by mixing H₂SO₄ solution with H₂O₂ solution for reaction acceleration. That is, H₂SO₄ and H₂O₂ are spouted from different nozzles. Both solutions are mixed at a mixing point in the shortest range just below the nozzle and H₂SO₄—H₂O₂ mixed solution (so-called sulfuric acid/hydrogen period) is prepared. The mixed solution is dripped in the vicinity of the center of a rotated photomask substrate and expanded by the effect of centrifugal force. By controlling the flow rate of H₂SO₄ and H₂O₂, the height of the mixing point P, and the number of revolution of the substrate, the temperature distribution of the mixed solution on the substrate surface is restrained to a minimum, and uniform cleaning might be possible. There has been described the wet exfoliation of chloromethylstyrene based resist material which is used for electron beam lithography or the like is possible.

However, this device adopts system in which two kinds of liquids are mixed after being sprayed from the nozzles, and further, utilizes heat of mixing of two kinds of liquids, therefore, liquid temperature, when reaching wafer surface, is difficult to be controlled. Practically, in FIGS. 2 and 3 in the same literature and related descriptions (paragraph 0035) of the embodiments 1 and 2, described is that wafer surface temperature distribution largely fluctuates depending on the nozzle height, and the optimum value in the nozzle height resides. Thus, the wafer surface temperature is hard to be controlled, therefore, it was difficult to stably obtain preferred treatment efficiency.

### SUMMARY OF THE INVENTION

In recent years, with microfablication of pattern due to high integration of the semiconductor device, higher cleanliness becomes required, conventional dip type cleaning method cannot cope with this circumstances, thus problems of adhesion of particles or metallic impurities to wafer surface has been made apparent.

In the manufacture process such as the lithography process, a large amount of particles or metallic impurities adhere on a wafer. In that condition, when performing the dip type SPM treatment for a plurality of wafers simultaneously while arranging in parallel, particles adhered to wafer rear surface are separated in the liquids, followed by generating phenomenon that the particles adhere to opposite face (wafer surface) of the wafers arranged in parallel. In order to remove the adhered particles, it is effective to add Megasonic in the dip type rinse treatment at after process, however, as a side effect, fine pattern on the wafer is damaged, so that, in some cases, the problem of the missing of the pattern occurs. This problem becomes serious in the case that particularly pattern width is not more than 150 nm. Further, the metallic impurities adhered to the wafer is dissolved in a solution, followed by being accumulated with reuse of the SPM, resulting in problem of metallic contaminants on wafer surface.

It is a non-limiting example of object of the present invention to manufacture a semiconductor device superior in element characteristic, and in a sufficient yield, in such a way that, after dry etching of the lithography process, or after ion implantation or wet etching to an opened resist pattern opened by the lithography process, resist is made to strip by wet cleaning, and particles or metallic impurities are sufficiently removed without damaging fine pattern.

According to the present invention, there is provided a method for manufacturing a semiconductor device comprising: forming a resist pattern, on an upper part of a semiconductor substrate, performing treatment with the resist pattern as a mask, and stripping the resist pattern while supplying resist stripping liquid to a resist pattern forming surface of the semiconductor substrate in a condition that the semiconductor substrate is made to rotate with the semiconductor substrate horizontally maintained, wherein the step of stripping resist pattern, comprising: supplying the resist stripping liquid to the resist pattern forming surface while rotating the semiconductor substrate in relatively high speed as a first step, and supplying the resist stripping liquid to the resist pattern forming surface while rotating the semiconductor substrate in relatively low speed as a second step after the first step.

According to the invention, included is the first step supplying the resist stripping liquid while rotating the semiconductor substrate relatively in high speed and the second step supplying the resist stripping liquid while rotating the semiconductor substrate relatively in low speed. For this reason, it is possible to effectively strip the resist pattern. Particularly, it is possible to effectively strip part, which is difficult to be stripped by the normal stripping treatment, such as resist hardening layer and the like in the resist pattern.

In the present invention, in the process performing the treatment, it is possible to adopt constitution performing ion implantation to the whole substrate with the resist pattern as a mask.

Further in the present invention, dose amount in the ion implantation is taken to as not less than 10¹⁴ cm⁻², the resist hardening layer generated within the resist pattern caused by the ion implantation may be made to stripped by the second step.

Further, in the present invention, there may be adopted constitution that the resist pattern is formed on the film provided on the semiconductor substrate, in the step of performing the treatment, upon performing dry etching of the film selectively with the resist pattern as the mask.

Here, the above described fine pattern may have part whose width is not more than 150 nm.

Further, the above described fine pattern may have part whose width is not more than 150 nm and whose height to the width is not less than 1.

The above described fine pattern may be a gate pattern, for instance, SiGe gate pattern having SiGe layer containing Si and Ge, polycrystalline or amorphous silicon gate pattern or metal gate pattern.

It may be possible to use following ones as the resist stripping liquid:
(i) Liquid including Caro's acid (peroxomonosulfate)
(ii) Organic solvent
(iii) Mixture of the first liquid including acid and the second liquid including hydrogen peroxide (for instance, mixture of sulfuric acid and oxygenated water)

It may be possible to adopt constitution that for instance, the first liquid including acid and the second liquid including hydrogen peroxide are made to mix within airtight space, obtained mixture is taken to as resist stripping liquid, and the resist stripping liquid is made to supply to the resist pattern forming surface via a nozzle. Further, the first liquid and the second liquid may be made to heat into predetermined temperature previously. Furthermore, it may be possible to adopt constitution supplying sulfuric acid to the resist pattern forming surface before the first step using the resist stripping liquid.

In the present invention, the resist stripping liquid may be made to supply to the resist pattern forming surface via a plurality nozzles. Further, the resist stripping liquid may be made to supply to the resist pattern forming surface after heating the resist stripping liquid previously into predetermined temperature.

Further, in the present invention, it me be possible to adopt constitution further comprising: performing rinse treatment of the semiconductor substrate, after the step of stripping the resist pattern, performing rinse treatment while supplying rinse liquid by the rinse liquid supplying unit on the semiconductor substrate maintained by the maintaining unit in the step of performing rinse treatment, and drying the semiconductor substrate maintained by the maintaining unit upon rotating the semiconductor substrate by the rotating unit.

Here the rinse liquid may be an alkali liquid, an electrolytic cathode water or a water with dissolved hydrogen gas. The electrolytic cathode water is a liquid, which is generated at cathode side when performing electrolysis of pure water or water including a little (not more than 0.5 mass %) ammonium ion. As a producing device for obtaining the electrolytic cathode water, although it is possible to use device of two-tank type electrolysis system, it is also possible to use three-tank type device. As the electrolytic cathode water, the water in which hydrogen gas generated at cathode by the electrolysis or hydrogen gas from a gas cylinder is made to dissolve into weak ammonia water, is required.

Further, in the present invention, it may be possible to adopt constitution further comprising: cleaning the semiconductor substrate from which the resist pattern is stripped with hydrofluoric acid, and cleaning the semiconductor substrate be subjected to cleaning by hydrofluoric acid with mixture of ammonia water and oxygenated water.

Further according to the present invention there is provided a resist stripping cleaning device having a treatment chamber for a single-wafer system, comprising: a maintaining unit maintaining a semiconductor substrate, a rotating unit rotating the semiconductor substrate maintained by the maintaining unit, a cleaning liquid supplying unit supplying a resist stripping liquid on the semiconductor substrate maintained by the maintaining unit, and a rinse liquid supplying unit supplying the rinse liquid on the semiconductor substrate maintained by the maintaining unit.

Further according to the present invention there is provided a resist stripping cleaning device having a first treatment chamber for a single-wafer system and a second treatment chamber for a single-wafer system, wherein the first treatment chamber for a single-wafer system comprising: a maintaining unit maintaining a semiconductor substrate, a rotating unit rotating the semiconductor substrate maintained by the maintaining unit, a cleaning liquid supplying unit supplying an acid resist stripping liquid on the semiconductor substrate maintained by the maintaining unit, and a rinse liquid supplying unit supplying the rinse liquid on the semiconductor substrate maintained by the maintaining unit, and the second treatment chamber for a single-wafer system comprising: a maintaining unit maintaining a semiconductor substrate, a rotating unit rotating the semiconductor substrate maintained by the maintaining unit, a cleaning liquid supplying unit supplying an alkali resist stripping liquid on the semiconductor substrate maintained by the maintaining unit, and a rinse liquid supplying unit supplying the rinse liquid on the semiconductor substrate maintained by the maintaining unit.

In this device, it may be possible to adopt constitution further comprising: a heating unit heating a resist stripping unit, and a thermally insulating unit thermally insulating the heated resist stripping liquid.

According to the present invention, it is possible to manufacture semiconductor device with superior element characteristic in a sufficient yield, in such a way that, after dry etching of the lithography process, wet cleaning stripes resists, and adhesion of particles or metal impurities is made to sufficiently suppress without damaging fine pattern.

### BRIEF DESCRIPTION OF THE DRAWINGS

The above and other objects, advantages and features of the present invention will be more apparent from the following description taken in conjunction with the accompanying drawings, in which:

FIG. 1 is an outline constitution view of a treatment chamber of a resist stripping cleaning device of the present invention;

FIG. 2 is a view showing evaluated results of the number of particles on the surface of a wafer after resist stripping process;

FIG. 3 is a view showing evaluated results of metal (Ge) amount adhering to the surface of a wafer after resist stripping process;

FIG. 4 is a view showing evaluated results of the number of generation of pattern peeling of the surface of wafer after resist stripping process;

FIG. 5 is a process sectional view of a process executed in an embodiment;

FIG. 6 is a view showing transition of the number of revolutions of the wafer in a process executed in the embodiment;

FIG. 7 is a view showing cleaning effect in the embodiment;

FIGS. 8(1 to 5) are views schematically showing resist stripping process;

FIG. 9 is a view showing cleaning effect in the embodiment;

FIG. 10 is a view showing cleaning effect in the embodiment;

FIG. 11 is an outline constitution view of a substrate treatment device 100 according to the embodiment;

FIG. 12 is a view showing a constitution example of a substrate mounting table;

FIG. 13 is a view showing constitution example of a mixing part;

FIG. 14 is an outline constitution view showing a substrate treatment device 100 according to the embodiment;

FIGS. 15A, 15B are views explaining position relationship between a nozzle and a semiconductor substrate;

FIG. 16 is an outline constitution view of the substrate treatment device in the embodiment;

FIG. 17 is an enlarged view of part including the mixing part, piping and nozzle;

FIG. 18 is a view showing transition of the number of revolution of the wafer;

FIG. 19 is a view showing transition of the number of revolution of the wafer;

FIG. 20 is a view showing transition on the number of revolution of the wafer;

FIG. 21 is a view showing transition of the number of revolution of the wafer; and FIG. 22 is a view showing constitution example of a mixing part.

### DETAILED DESCRIPTION OF THE EMBODIMENT

The invention will now be described herein with reference to illustrative embodiments. Those skilled in the art will recognize that many alternative embodiments can be accomplished using the teachings of the present invention and that the invention is not limited to the embodiments illustrated for explanatory purposed.

Hereinafter, there will be described preferred embodiment of the invention while exemplifying a method for manufacturing the semiconductor device having a gate electrode including SiGe layer.

First, formed is a silicon oxide film to become a gate oxide film by thermal oxidation on the silicon substrate on which element isolation region is formed. It is possible to appropriately set thickness of the silicon oxide film, for instance, within the range to be 1 to 10 nm.

Next, formed is SiGe film by, for instance, LP-CVD (Low pressure chemical vapor deposition) on the silicon oxide film. It is possible to appropriately set thickness of the SiGe film, for instance, within the range to be 1 to 400 nm. The composition of the SiGe film is capable of being appropriately set, however, it is possible to set Ge content from the viewpoint of element characteristic within the range to be 10 to 40 atom %. The Si content at this time, when SiGe layer is two-component system of Si and Ge, is capable of being set within the range to be 90 to 60 atom %.

Next, a film is formed on the SiGe film. The film thickness is capable of appropriately being set, for instance, with the range to be 10 to 400 nm. It is possible to use a polycrystalline silicon film; and it is possible to form the polycrystalline silicon film in such a way that, for instance, deposited by the CVD method is a polycrystalline silicon film, while doping n-type or p-type impurities at the time of deposition, or doping n-type or p-type impurities by an ion implantation after deposition.

Next, after forming a resist film with applying photoresist on the film (or on the impurities doped SiGe film in the case without providing the film), the predetermined resist pattern is formed by the lithography.

Next, formed is a gate electrode and a gate insulating film composed of the SiGe layer and the conductive material layer, while carrying out dry etching of the film, the SiGe film and the silicon oxide film, with the resist pattern as a mask. It is possible to set dry etching condition appropriately, specifically, for instance, it is possible to carry out the dry etching by a reactive ion etching method using Cl₂, HBr, or the like as an etching gas.

In such a way as above, supplied is resist stripping liquid on the semiconductor substrate on which the gate pattern is formed, after that, resist pattern is stripped together with etching residue, by the wet treatment of the single-wafer system.

As a method for stripping resist pattern, in some cases, dry treatment such as ashing or the like other than the wet treatment is performed, since it is such treatment that high energy such as oxygen plasma or the like is utilized, the substrate may easily be damaged, and it becomes necessary for the treatment to remove ashing residue, so that the wet treatment using resist stripping liquid is advantageous.

It is preferred that the resist stripping liquid is capable of sufficiently stripping the resist pattern after dry etching by the single-wafer system treatment. As the resist stripping liquid, various inorganic solvents and organic solvents are known, specifically, for instance, SPM (mixed liquid of sulfuric acid and hydrogen peroxide) indicated as the inorganic solvent, while, as the organic solvent, a solvent containing phenol and halogen-based solvent as main components, an amine-based solvent, and a ketone-based solvent such as cyclopentanone, methyl ethyl ketone or the like are indicated. The resist after dry etching is denatured in connection with its surface, so that, generally, solubility to solvent is low in comparison with the resist before dry etching, therefore, resist residue easy to remain, so, it is preferable that SPM cleaning with high resist stripping effect is made to perform.

In respect to performance of removal and cleaning effect, composition of SPM is capable of being set to be sulfuric acid: 30 mass %, oxygenated water=1:1 to 8:1 (volume factor); and working temperature may be within the range of 100 to 150° C.

Supply of the resist stripping liquid is performed in such a way that the resist stripping liquid brings into contact with the whole resist pattern forming surface of the semiconductor substrate; specifically, it is possible to strip resists while supplying the resist stripping liquid continuously or intermittently, or providing predetermined retention time after the supply. On this occasion, uniform contact between the surface of the semiconductor substrate and the resist stripping liquid becomes possible, upon maintaining the semiconductor substrate with the rotatable stage to be rotated; owing to this, it is possible to carryout more effective cleaning. Further, the resist stripping liquid is made to prevail immediately to semiconductor substrate entirely upon rotating the substrate at relatively high speed on the supply starting time of the resist stripping liquid, thereafter, it is also possible to maintain the resist stripping liquid during predetermined time while rotating the substrate at relatively low speed or stopping the revolution.

Further, it is preferred that the resist stripping liquid may be supplied to the surface of the semiconductor substrate after being heated by the heating means such as heater and the like up to predetermined temperature previously. At this time, it is preferred that the resist stripping liquid within the line is made to maintain at the predetermined temperature, while providing heat insulator such as a thermally insulating material or a heater for heat insulation. In the case of using the SPM, it is preferred that temperature is set to the range to be 100 to 150° C. By using heated resist stripping liquid, it is possible to obtain sufficient cleaning effect with short time.

It may be preferred to supply the heated resist stripping liquid on the heated semiconductor substrate while heating the semiconductor substrate, however, because it is possible to obtain sufficient cleaning effect without heating semiconductor substrate, in respect to simplification of device constitution and treatment operation, it is preferred that the heated resist stripping liquid is made to supply on the semiconductor substrate at ordinary temperature. Further, although it is possible to supply the resist stripping liquid at ordinary temperature on the heated semiconductor substrate, particularly, in case of using the SPM, specific heat of the SPM is large and viscosity is high, and because of the single-wafer system treatment, contact time between the substrate and the cleaning liquid is relatively short, therefore, temperature of the cleaning liquid supplied on the substrate is difficult to increase up to required temperature, resulting in deterioration of cleaning effect in comparison with the case using the heated cleaning liquid.

In the present invention, particularly, it is preferred that the SPM is used as the resist stripping liquid. The SPM has high viscosity and high corrosion characteristic, therefore, conventionally, the SPM is generally used in dip type treatment, consequently, the single-wafer system treatment with the SPM was not carried out in respect to the problem on the device or the like, in a condition where it is necessary for the device to provide heat resistance or acid resistance structure, for that reason, the single-wafer system treatment has not been carried out. In particular, in resist peeling after dry etching of the lithography process, as described above, it is known that resist becomes difficult to remove in comparison with the condition before dry etching, therefore, there has been no case that the single-wafer system treatment dare to be performed in that the treatment time of single-wafer system treatment generally becomes short in comparison with the dip system. That is, conventionally, there has been no technical idea executing the single-wafer system treatment while supplying heated SPM on the semiconductor substrate, because of resist peeling after dry etching of the lithography process.

After stripping the resist pattern in such a way as above, rinse treatment in the single-wafer system is carried out while supplying rinse liquid on an upper face of the semiconductor substrate. By this rinse treatment, it is possible to remove the resist stripping liquid on the surface of the semiconductor substrate and residues within the stripping liquid. It is possible to appropriately use pure water as the rinse liquid. As the other rinse liquid, it is possible to use CO₂ water dissolving CO₂ into pure water, and reducing water dissolving hydrogen gas into pure water. It is also possible to add traces (degree of 10 ppm) of ammonium hydroxide to the reducing water. On the occasion of the rinse treatment, the semiconductor substrate is made to maintain on rotatable stage to rotate, so that uniform contact between the surface of the semiconductor substrate and the rinse liquid becomes possible, and it is possible to carry out more effective rinse.

It is possible to carry out drying treatment after the rinse treatment in such a way as to maintain the semiconductor substrate onto the rotatable stage, and to cause the stage to be subjected to high speed revolution (for instance, 1000 rpm). On this occasion, it is possible to perform drying treatment while blowing isopropyl alcohol vapor or dry inert gas. Effective drying becomes possible due to high velocity revolution, and further blowing of gas.

The resist stripping process and the rinse treatment process are preferably performed continuously within a treatment chamber of the single-wafer system. Further, it is also possible to execute the drying process within one treatment chamber of the single-wafer system. This enables to avoid the contamination during the carrying the wafers.

In the case of using acid resist stripping liquid such as SPM or the like, after that treatment, when treating the semiconductor substrate with alkali chemical liquid, it is preferable to execute the treatment in different treatment chamber. It is possible to prevent generation of particles caused by formation of salt by acid component and alkali component within the chemical liquid.

After the process described above, it is possible to manufacture the predetermined semiconductor device upon providing the semiconductor substrate in which gate pattern is formed for the known manufacturing process.

Here, there is described the embodiment while taking the case of forming the SiGe gate pattern as an example, further, the present invention may also be preferable, in the case that metal gate pattern made of Tungsten or Molybdenum or the like are made to form, or metal gate pattern made of NiSix, ZrN, TiN, IrSix, PtSix or the like are made to form. Further, the present invention is preferable, in the case that formed is fine pattern having part in which line width is not more than 150 nm, and further formed is fine pattern having part in which line width is not more than 150 nm and its height with respect to the line width is not less than 1. In particular, the present invention is preferable, in the case that formed is fine gate pattern having gate length to be not more than 150 nm, and further formed is fine gate pattern having gate length to be not more than 150 nm and its ratio of gate height with respect to the gate length is not less than 1. This fine pattern is easily subjected to damages such as pattern peeling when adding Megasonic in dip type rinse treatment in order to remove particles attached to the substrate at the conventional dip type resist stripping treatment. According to the present invention, it is not necessary to add such Megasonic, consequently, it is possible to strip resists while suppressing adhesion of particles or metal impurities without damaging fine pattern.

In the manufacturing process described above, further, the semiconductor substrate whose resist pattern is stripped to be subjected to rinse treatment is made to clean (DHF cleaning) with hydrofluoric acid (dilute hydrofluoric acid: DHF), next, if necessary, there is provided a process in which rinse treatment is made to perform, after that, the semiconductor substrate cleaned by DHF is made to clean (APM cleaning) with a mixture of ammonia water and oxygenated water (APM), subsequently, if necessary, a process of rinsing may preferably be executed.

The DHF is very high in stripping power of the dry etching residue, and the APM is very high in particle stripping power, therefore, by executing these cleanings, both of the dry etching residue and the particles can be removed more effectively.

Concentration of hydrogen fluoride of DHF is favorable to be not less than 0.05 mass %, more favorable to be not less than 0.1 mass %, and particularly favorable to be not less than 0.13 mass %, on the other hand the concentration is favorable to be not more than 1.0 mass %, more favorable to be not more than 0.7 mass %, and particularly favorable to be not more than 0.5 mass.

When the concentration of hydrogen fluoride of DHF is high, stripping power of the dry etching residue becomes large, however, when the concentration of hydrogen fluoride is too high, etching rate of the gate oxide film becomes large, thus the etching rate becomes large in such a degree that side etching becomes problem.

Further, when the concentration of hydrogen fluoride is too high, it becomes necessary to shorten cleaning time in respect to prevention of the side etching, so the dry etching residue easily remains, and further, cleaning operation becomes difficult in respect to control of the cleaning time. To the contrary, when the concentration of hydrogen fluoride is low, the etching rate of the gate oxide film becomes small, so that the side etching of the gate oxide film is capable of being suppressed, however, stripping power of the dry etching residue becomes small. Consequently, upon setting composition of the first chemical liquid within the above described range, it is possible to further sufficiently remove the dry etching residue adhering to the semiconductor substrate while further sufficiently suppressing the side etching of the gate oxide film.

A working temperature of the DHF is favorable to be not more than 40° C., more favorable to be not more than 35° C., and particularly favorable to be not more than 30° C. By setting the working temperature of the DHF within the above described range, it is possible to further sufficiently suppress the side etching of the gate oxide film. Further, the working temperature of the DHF is favorable to be not less than 5° C., more favorable to be not less than 10° C., and particularly favorable to be not less than 15° C. By setting the working temperature of the DHF within the above described range, it is possible to further sufficiently remove the dry etching residue adhering to the substrate.

As one example of DHF cleaning described above, it is possible to execute DHF cleaning in such a way that, with using a single-wafer system cleaning device, DHF of concentration of hydrogen fluoride 0.5 mass % at liquid temperature 20° C. is made to spray from a spray nozzle while rotating (spin) the semiconductor substrate maintained on the stage during treatment period of time to be 20 to 30 seconds.

On the other hand, ammonia concentration of APM used for APM cleaning is favorable to be not less than 0.05 mass %, more favorable to be not less than 0.1 mass %, and particularly favorable to be not less than 0.2 mass %. Further, ammonia concentration of APM is favorable to be not more than 1.5 mass %, more favorable not more than 1 mass %, and particularly favorable to be not more than 0.6 mass %.

Content ratio (hydrogen peroxide/ammonia; mass reference) of hydrogen peroxide to ammonia within AMP is favorable to be not less than 1, more favorable to be not less than 1.1, and particularly favorable to be not less than 1.2. Further, Content ratio (hydrogen peroxide/ammonia; mass reference) of hydrogen peroxide to ammonia within AMP is favorable to be not more than 5, more favorable to be not more than 3, and particularly favorable to be not more than 2.

Etching rate of SiGe layer tend to become small with decreasing ammonia concentration within APM; while, the ammonia concentration becomes too low, stripping power of the particles tends to decrease. On the other hand, stripping power of the particles of the APM tends to become large with increasing content ratio of hydrogen peroxide to ammonia within the APM, up to arrival at specific ratio. Further, to make content ratio of hydrogen peroxide to ammonia within APM too large is not preferable in respect to cost.

In this respect, by setting composition of the APM within the above described range, it is possible to further sufficiently remove the particles adhering to the semiconductor substrate while sufficiently suppressing the side etching of the SiGe layer.

The working temperature of the APM, in respect to suppression of the side etching of the SiGe layer or temperature control or the like, is preferable to be not more than 45° C., more preferable to be not more than 40° C. and particularly preferable to be not more than 35° C. Further, it is preferable that the working temperature of the APM is within the range close to the room temperature as near as possible in respect to temperature control or energy cost or the like, so, for instance, with the above temperature range as upper limit, it is possible to set allowable tolerance temperature to be not less than 5° C., to be not less than 10° C., further, to be not less than 15° C.

When attempting to perform cleaning of the semiconductor substrate while using mixture of ammonia water and oxygenated water with relatively high liquid temperature and relatively high concentration according to the conventional cleaning method, after forming the gate pattern and the gate oxide film pattern upon performing patterning by the dry etching, not the degree of SiGe layer, but the gate oxide film is subjected to the side etching in some degree. For that reason, in the conventional cleaning method, the cleaning condition is controlled such that side etching amount of the gate oxide film is made to stay within permitted limit with which deterioration of element characteristic does not become problem, such as for instance, not more than 1 nm. In the present invention, it is possible to make the APM composed of mixture of the ammonia water and the oxygenated water lower concentration than the chemical liquid used conventionally, therefore, it is possible to sufficiently suppress or prevent the side etching of the gate oxide film caused by the APM in the APM cleaning process. Further, in the APM cleaning process, it is possible to sufficiently suppress or prevent the side etching of the gate oxide film, therefore, it is possible to sufficiently secure permitted limit of side etching amount of the gate oxide film, as a result, in the DHF cleaning process, even though hydrofluoric acid having etching characteristic to the oxide is made to use, it is possible to remove the etching residue while suppressing the side etching amount of the gate oxide film within its permitted limit.

As one example of APM cleaning described above, it is possible to execute APM cleaning in such a way that, with using a single-wafer system cleaning device, APM of composition of 30 mass % ammonia water: 30 mass % oxygenated water: water=1:1:50 (volume ratio), at liquid temperature 35° C. is made to spray from a spray nozzle while rotating (spin) the semiconductor substrate maintained on the stage during treatment period of time to be 30 seconds to 2 minutes.

It is preferable that the above described DHF cleaning process and its rinsing process, and the APM cleaning process and its rinsing process are made to carry out continuously within cleaning device of one single-wafer system successively following the resist stripping process and its rinsing process. Further, it is preferable that, finely, succeeding drying process is made to continuously perform within the cleaning device of one single-wafer system. Owing to this, conveyance of the semiconductor substrate between devices becomes unnecessary, further, it is possible to prevent contaminants of the substrate at the time of conveyance. It should be noted that, in respect to prevention of particle generation, the alkali APM cleaning may preferably be executed in different treatment chamber from the treatment chamber in which treatment by acid chemical liquid (SPM or DHF) is carried out.

As preferred single-wafer system cleaning device for manufacturing method of the present invention, it is possible to use a resist stripping cleaning device having a treatment chamber of a single-wafer system that is provided with a maintaining unit maintaining a semiconductor substrate, a rotating unit rotating the semiconductor substrate maintained on the maintaining unit, a cleaning liquid supplying unit supplying resist stripping liquid on the semiconductor substrate maintained on the maintaining unit, and a rinse liquid supplying unit supplying the rinse liquid on the semiconductor substrate maintained on the maintaining unit. In the case of performing another cleaning such as DHF cleaning or the like after resist stripping process, it may be preferable of further possessing a chemical liquid supplying unit.

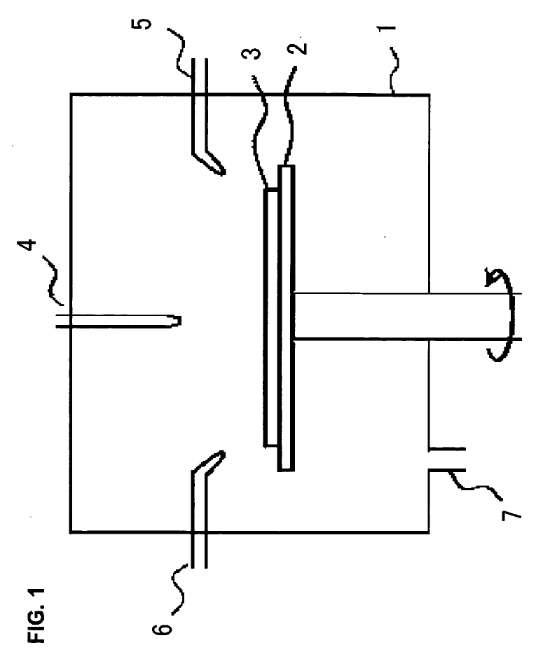

As a single-wafer system cleaning device described above, for instance, it is possible to use a cleaning device having a treatment chamber shown in FIG. 1. This cleaning device is provided with a rotatable stage 2 maintaining a wafer 3 in the treatment chamber 1. Maintaining of a wafer is capable of being performed in such a way as to provide a suction mechanism on the stage 2, or to provide wafer hold-down tools on the periphery of the stage. Above the stage 2, there are provided a resist stripping liquid supply nozzle 4, a rinse liquid supply nozzle 5, and a supply nozzle 6 for another chemical liquid such as DHF or the like such that it is possible to supply various chemical liquids or rinse liquids onto the wafer 3 maintained on the stage 2. Inner surface of the treatment chamber or contact part to chemical liquid such as supply nozzles, stages and the like are constituted or coated with chemical resistance (acid resistance/heat resistance) materials such as quarts or Teflon (trade mark) or the like. There is provided a waste liquid drain 7 on the bottom of the treatment chamber 1, from the waste liquid drain 7, chemical liquid or pure water supplied to an upper face of the wafer is discharged. Further, there may be provided a supply port for inert gasses such as nitrogen gas or argon or the like in order to maintain treatment atmosphere into constant condition, with this circumstance, it is also possible to provide an exhaust port. Various chemical liquids such as resist stripping liquid and the like are maintained at predetermined temperature within a storage tank, followed by being subjected to pressure feed by a supply pump to be discharged from a supply nozzle. On this occasion, it is possible to coat the supply line with thermally insulating material, or to adjust temperature with a heater.

When carrying out treatment using alkali chemical liquid such as APM or the like, after carrying out treatment using acid chemical liquid such as SPM, DHF, or the like, it is preferable that provided is a cleaning device having a treatment chamber with the same constitution as the above described treatment chamber other than the constitution in which the supply nozzle for alkali chemical liquid is provided instead of the resist stripping liquid supply nozzle, separately within one device. Conveyance of the semiconductor substrate between different treatment chambers is capable of being executed in such a way as to provide known conveyance unit.

Next, there will be described preferred embodiment of the present invention with reference to the drawings.

### First Embodiment

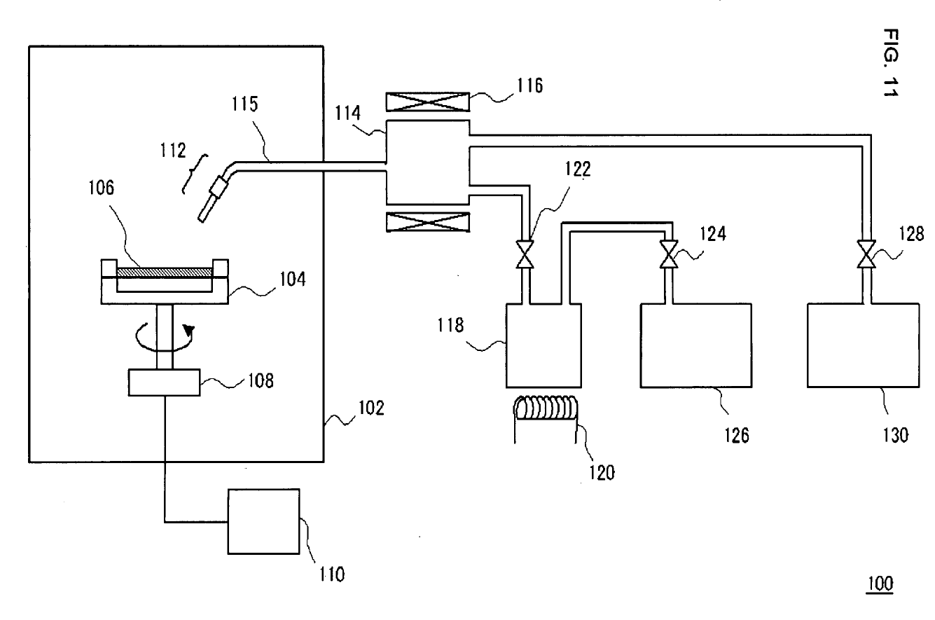

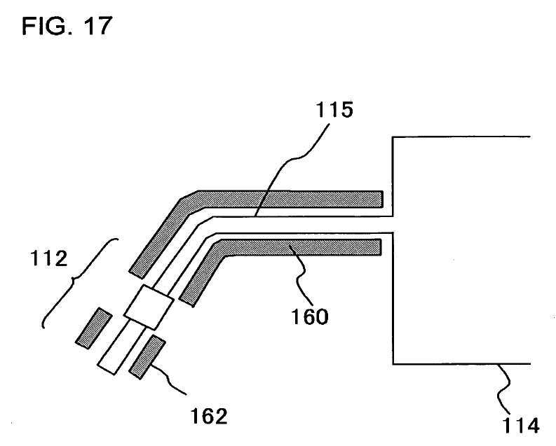

FIG. 11 is a view showing outline constitution of a substrate treatment device 100 according to the present embodiment. This substrate treatment device 100 is provided with a treatment chamber 102 including a substrate mounting table 104, a first container 126 accommodating a first liquid supplied to the surface of the semiconductor substrate 106, a second container 130 accommodating a second liquid supplied to the semiconductor substrate 106, a mixing part 114, which is communicated with the first container 126 and the second container 130, producing mixture while mixing the first and the second liquids supplied from these containers, a nozzle 112, which communicates with a mixing part 114, supplying the mixture to surface of the semiconductor substrate 106, and a piping 115, which connect the mixing part 114 with the nozzle 112, introducing the mixture from the mixing part 114 to the nozzle 112. In periphery of the piping 115, piping heater 160 heating the piping 115 is disposed (FIG. 17).

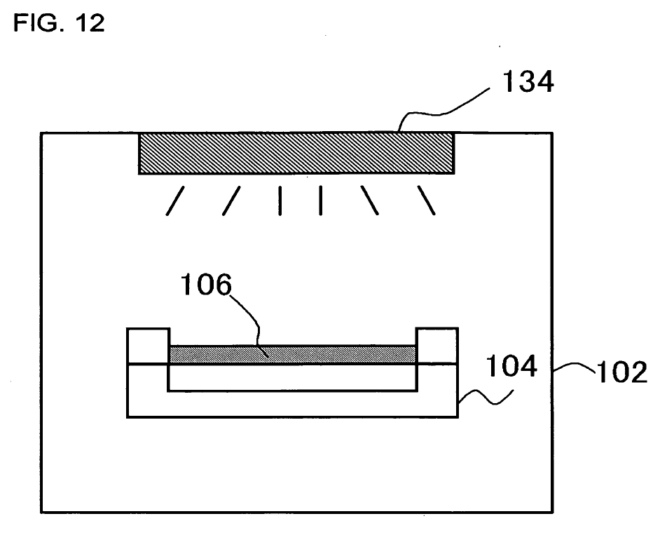

A substrate mounting table 104 maintains the semiconductor substrate 106 to become objects to be treated. The substrate mounting table 104, which is connected to a motor 108, is constituted in such a way as to rotate with the condition where the semiconductor substrate 106 is made to maintain horizontally. The semiconductor substrate 106 rotates with an axis passing through the center of the substrate, and perpendicular to the surface of the substrate as axis. It may preferable that there is provided a heating part on the substrate mounting table 104 or its periphery, so that the semiconductor substrate 106 is heat insulated by the heater into predetermined temperature. FIG. 12 is a view showing an example of such constitution. In the constitution in FIG. 12, an infrared heater 134 is disposed above the substrate mounting table 104, owing to this, the surface of the semiconductor substrate 106 is heated.

A rotation controller 110 controls rotation speed of the motor 108. According to consideration of the inventor, it has become clear that, during the period of treating process, in some cases, treatment efficiency is improved upon causing the number of revolution of the substrate to vary appropriately. For instance, in the resist stripping treatment carried out in the present embodiment, it has become clear that resist stripping efficiency is sharply improved in a condition where, initially, the substrate rotates relatively high rotational speed, after that, the substrate rotates relatively low rotational speed.

Its reason is not necessarily apparent, however, it is guessed below. When performing impurity implantation of high dose-rate, formed on the surface of the resist is hardening layer. Such hardening layer is, generally, difficult to remove. Accordingly, increased is chance where surface of the semiconductor substrate 106 comes into contact with fresh chemical liquid upon high speed revolution of the substrate; so that it is possible to activate removal of the hardening layer, accordingly stripping treatment efficiency is improved. On the contrary, after being stripped hardening layer, the substrate is not necessarily made such high speed revolution, but it is preferable that the substrate is made to rotate in low speed revolution to cause retention time of liquid on the surface of the substrate to be long time, so that it leads to reduction of quantity consumed of chemical liquid. The rotation controller 110 is capable of realizing rotational speed profile depending on treatment content described above. Although there is no particular limitation in control system by the rotation controller 110, for instance, it is possible to use system driving a motor 108 based on a table, while maintaining a table in which time is made to correspond to the number of revolution.

The first container 126 and the thermally insulator 118 accommodate the first liquid used for treatment. In the present embodiment, used as the first liquid is sulfuric acid. Sent for the thermally insulator 118 by a pump not shown in the drawings is the first liquid accommodated in the first container 126. Its liquid amount is adjusted by a control valve 124. The heater 120 is formed at periphery of the thermally insulator 118, thus the first liquid sent from the first container 126 is thermally insulated into predetermined temperature. In the present embodiment, the predetermined temperature is 80 to 100° C. The first liquid accommodated in the thermally insulator 118 is sent to the mixing part 114 while being adjusted its feeding amount by the control valve 124.

The second container 130 accommodates the second liquid used for the treatment. In the present embodiment, used as the second liquid is oxygenated water. The second container 130 is maintained to room temperature (20 to 30° C.); and the second liquid is directly supplied to the mixing part 114 from the second container 130. Feeding amount of the second liquid is adjusted by the control valve 128.

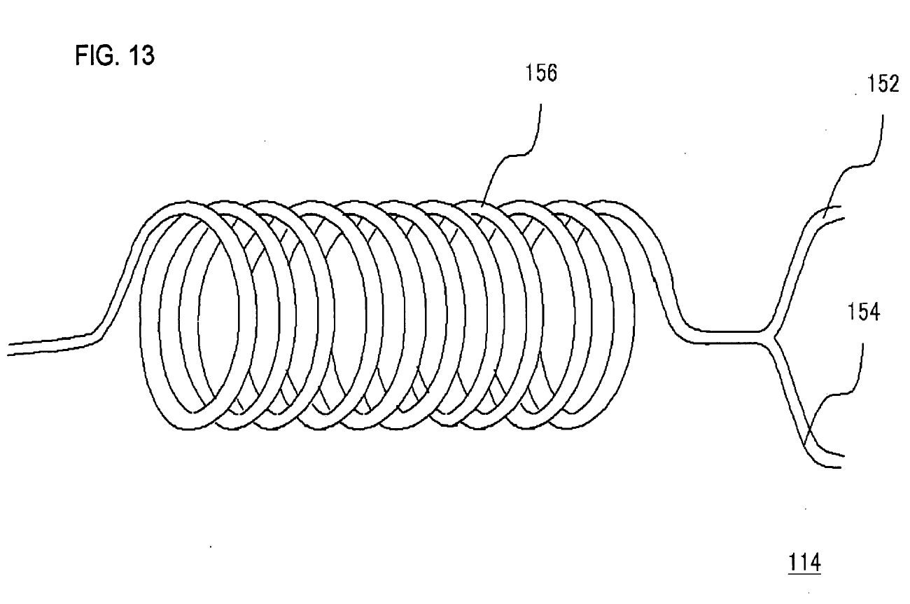

The mixing part 114 mixes the first liquid supplied from the thermally insulator 118 with the second liquid supplied from the second container 130. As mixing systems, it is possible to use various forms. FIG. 13 is a view showing one example of constitution of the mixing part 114. As shown in the drawings, the mixing part 114 is provided with a piping 156 composed of a spiral tube of hollow structure, and a first introducing port 152 and a second introducing port 154 respectively introducing the first liquid and the second liquid to the piping 156.

By using the mixing part 114 with such constitution, the first and the second liquids are efficiently mixed with spirally moving along an inner wall of the mixing part. FIG. 22 shows another constitution example of the mixing part 114. In this example, at periphery of the piping 156 to be identical with FIG. 13, tubular heater 166 is disposed. The piping 156 is disposed on the inside part of the tubular heater 166. The tubular heater 166 has an inlet 170 and an outlet 168 for warm water, and heat medium circulates in the inside part thereof. For instance, glass is taken as composition material of the tubular heater 166.

In the present embodiment, the first and the second liquids, that is, the sulfuric acid and the oxygenated water are mixed, resulting in generation of reaction heat, so that temperature of the mixture becomes not less than 100° C.; and treatment efficiency is enhanced upon supplying such mixture with high temperature to the semiconductor substrate 106. However, during a period when the supply of mixture for the semiconductor substrate 106 is stopped, the mixing part 114 is cooled, so it is conceivable that temperature of a liquid remaining inside decreases. Consequently, in the device of FIG. 11, there is provided the heater 116 around the mixing part 114 to suppress cool down of the remaining liquid.

The nozzle 112 supplies the mixture created at the mixing part 114 to the surface of the semiconductor substrate 106. The mixture sent from the mixing part 114 is introduced to the nozzle 112 via the piping 115. The nozzle 112 sprays mixture toward predetermined portion of the semiconductor substrate 106.

FIG. 17 is an enlarged view of part including the mixing part 114, the piping 115 and the nozzle 112. The nozzle 112 supplies the mixture, which has become high temperature due to reaction heat, to the semiconductor substrate 106. In this respect, treatment efficiency for the semiconductor substrate 106 enhanced, however, it is conceivable that, during the period when supply of the mixture for the semiconductor substrate 106 is stopped, temperature of a liquid remaining inside of the nozzle 112 decreases. Consequently, as shown in FIG. 17, in the present embodiment, the heater 162 is arranged around the nozzle 112 to suppress cool down of the remaining liquid.

Further, the piping heater 160 is arranged around the piping 115. Owing to this, during a period the mixture is fed from the mixing part 114 to the nozzle 112, the mixture is maintained in high temperature, so that it is possible to make temperature or composition of the mixture stable.

Next, there will be described treatment process of the substrate using the above device.

In the present embodiment, executed is the process composed of following steps.
(i) A resist is formed on the silicon.
(ii) Patterning process of the resist is carried out.
(iii) An ion implantation is carried out with the resist as a mask. In the present embodiment, provided that, ion species: As, injection concentration: 5×10¹⁴ cm⁻².
(iv) The resist is made to peel with the mixture (SPM) of sulfuric acid and oxygenated water.

In the above step (iv), used is the device indicated in FIG. 11 or the like. Before carrying out treatment (iv), the second container 130 should be prepared in a condition that inside thereof is filled with oxygen water, and the first container 126 should be prepared in a condition that inside thereof is filled with sulfuric acid. Predetermined amount of the sulfuric acid is made to introduce to the thermally insulator 118 from the first container 126, to be subjected to thermally insulating by the heater 120 at 80 to 110° C. The circumstance is maintained in this condition and preparation is performed, thereafter, treatment is started. First, flow rate of the first liquid is adjusted by the control valve 122, followed by adjusting flow rate of the second liquid by the control valve 128, to introduce these liquids to the mixing part 114. Within the mixing part 114, these are mixed to become SPM. The mixture, which reaches liquid temperature of 100 to 120° C. due to exothermic reaction by mixing, is made to introduce onto the surface of the semiconductor substrate 106.

The number of revolution of the semiconductor substrate 106 in the treatment is controlled in such a way as following conditions.
(a) Up to 15 seconds elapsed from start: 500 revolutions per minute
(b) From 15 seconds elapsed to 40 seconds elapsed: 15 revolutions per minute

Due to above (a), stripped efficiently is resist hardening layer generated by high concentration dose-rate. Next, due to above (b), removed is the resist residing on lower part than the hardening layer.

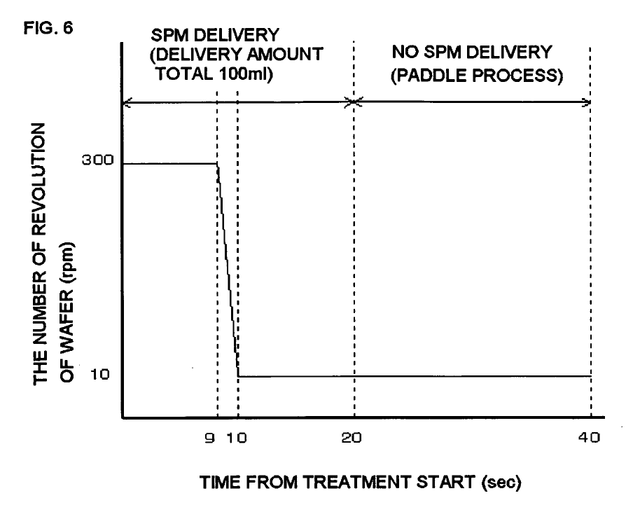

It should be noted that wafer revolutions transition can take various forms other than that described above. For instance, FIG. 6 shows one example thereof.

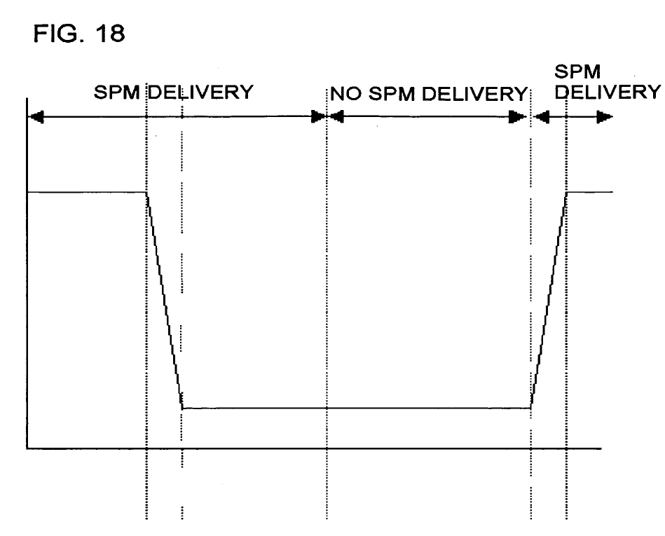

Further, the profiles shown in FIGS. 18 to 21 may preferably taken.

In the profile shown in FIG. 18, at the time the hardening layer on the wafer periphery part can be stripped, revolution is made to return to high speed revolution again and new SPM of high temperature is sprayed entirely on the wafer, owing to this, a little remaining resist residue on the surface is made to remove completely.

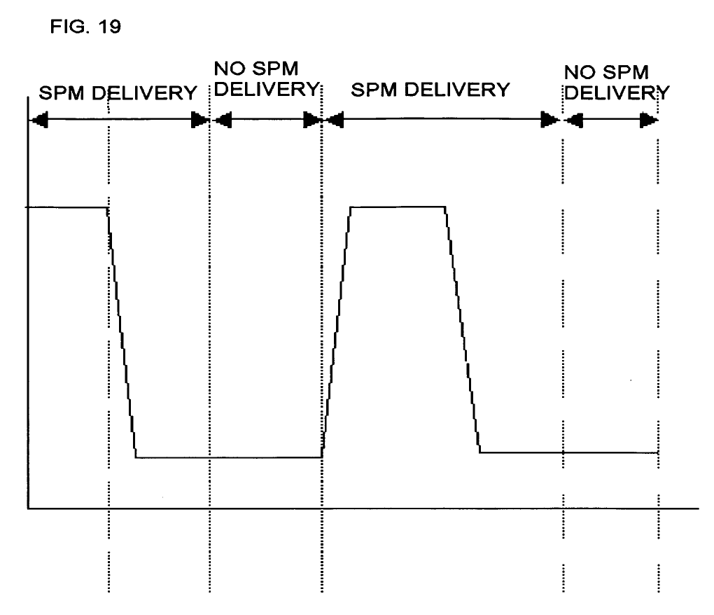

In the profile shown in FIG. 19, in the case that resist surface hardening layer depending on I/I (Ion Implantation) is thickly formed caused by repetition of high speed revolution and low speed revolution, area in which the hardening layer is not stripped becomes large at the time of high speed revolution/SPM delivery. Consequently, in this case, it becomes not possible to remove the hardening layer entirely at the low speed revolution, in one-time high speed to low speed revolution treatment. For this reason, area of resist hardening layer remaining at the time of final low speed revolution is made to reduce, upon repeating high speed revolution/delivery and low speed revolution again. Owing to this, it becomes possible to efficiently remove the resist.

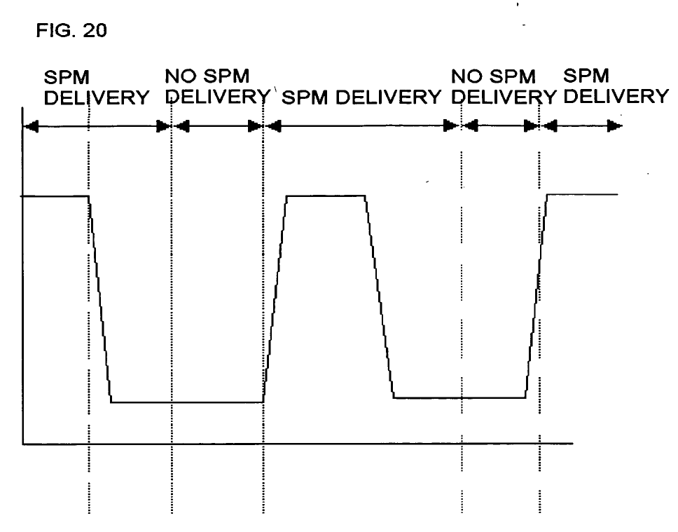

The profile shown in FIG. 20, like the profile of FIG. 19, is an efficient treatment method in the case that the resist hardening layer depending on I/I is thickly formed, like the profile of FIG. 18, by the high speed revolution and delivery at the final treatment, a little remaining of resist residue on the surface is made to remove entirely.

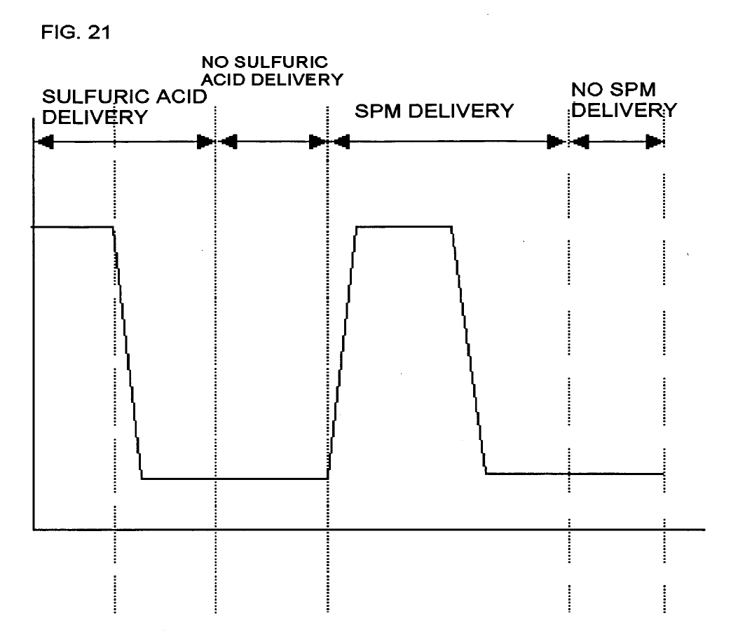

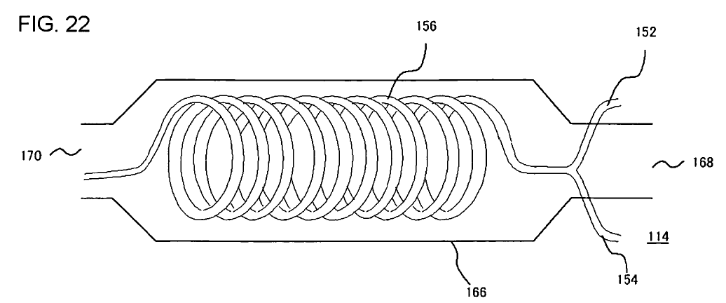

The profile shown in FIG. 21, like the profile of FIG. 19, is one of efficient treatment methods of the case where the resist hardening layer depending on I/I is thickly formed, in the first stage, the hardening layer is made to soften by only dense sulfuric acid, and in the second stage, resist dissolution and removal is performed by SPM delivery. Further, like the profile of FIG. 20, the SPM delivery at the high speed revolution in the final treatment may be carried out. Concerning peeling of the resist subjected to ion implantation, it may preferable to perform the single-wafer SPM treatment after light ashing. For instance, in the ion implanted resist of 1E15, it may preferable to perform the single-wafer SPM treatment, after light ashing during the period of time to be degree of 20 to 60 sec.

Hereinafter, there will be described effect of device and method according to the present embodiment.

The device according to the present embodiment adopts a system in which the first and the second liquids are mixed in the mixing part 114, the mixture (SPM) is made high temperature while utilizing the heat generated at the time of the above mixing, and the mixture with high temperature is made to spray on the semiconductor substrate 106.

Liquid temperature is made to increase while utilizing reaction heat by mixing immediately before spraying to the semiconductor substrate 106, therefore, it is not necessary to provide extra mechanism for heating, so that treatment liquid can be made high temperature with simple structure, and it is possible to improve treatment efficiency.

Further, in the present embodiment, the downstream side (semiconductor substrate 106 side) from the mixing part 114 becomes constitution being subjected to thermally insulating by the heater. For this reason, the mixture with increased temperature due to reaction heat becomes possible to supply to the semiconductor substrate 106 without substantially lowering the temperature. Owing to this, it is possible to stably realize preferred treatment efficiency.

Further, the device according to the present embodiment adopts treatment of a single-wafer system treating the wafer one-by-one using treatment liquid, not the dip system dipping many wafers into the same treatment liquid. In the dip system, contaminants removed from the wafer surface are dissolved or dispersed in the solution, thereafter, the problem that the contaminants re-adhere to the reverse side of another neighboring wafer easily takes place. In this respect, the present embodiment performs treatment of the single-wafer system, therefore, such problem does not take place, so that it is possible to realize cleanliness with higher level.

Further, in the present embodiment, there is adopted constitution in which liquid is sprayed from the nozzle 112 after the first and the second liquids are mixed previously in the mixing part 114. By mixing of two liquids in the inside of the mixing part 114 of airtight structure, Caro's acid (peroxosulfate H₂SO₅) is generated, and the mixture including fixed amount of the Caro's acid is sprayed to the semiconductor substrate 106 from the nozzle 112, therefore, it is conceivable that preferred resist stripping efficiency is obtained. Although the condition that the Caro's acid is easily generated is not necessarily clear, it is conceivable that, in the case where two liquids are made to mix in the mixing part 114 of the airtight structure as the present embodiment, there is tendency that the Caro's acid is stably generated. As later described in paragraph of Example, in the mixing of two liquids after discharging to outside from the nozzle, it is difficult to obtain stable resist stripping efficiency, thus it is desirable to provide a mixing part of airtight structure as the present embodiment.

Further, in the present embodiment, the sulfuric acid and the oxygenated water are mixed once within airtight space, followed by further heating by the heater 116, while maintaining the Caro's acid (oxide species) generated by mixing into SPM liquid. Owing to this, it is possible to stably improve resist stripping efficiency.

### Second Embodiment

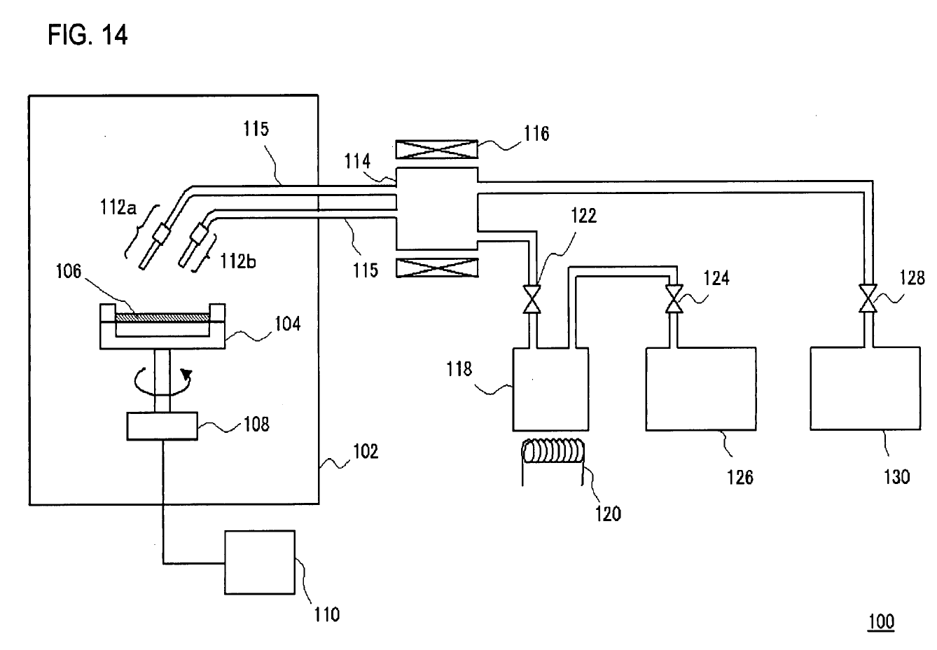

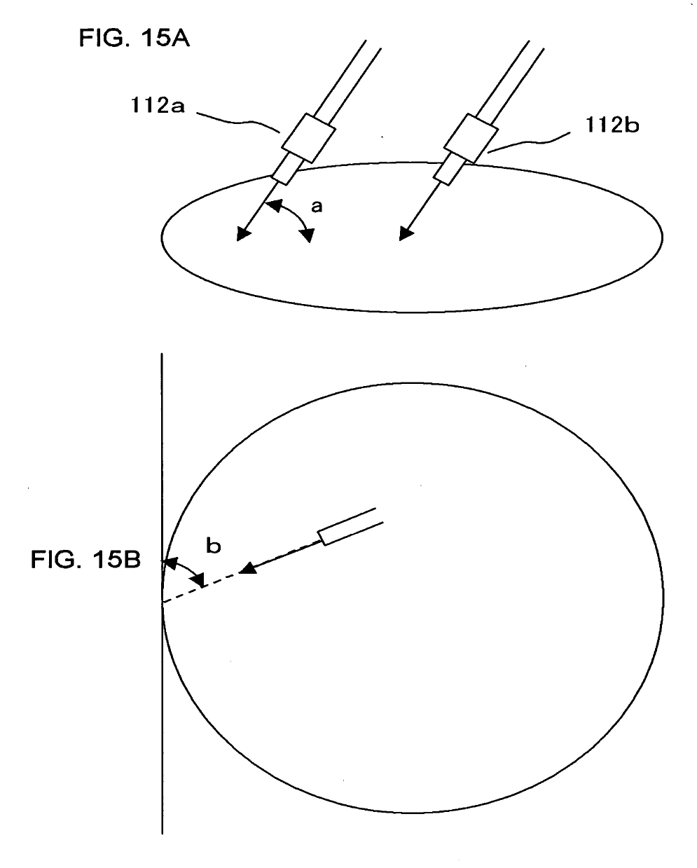

The present embodiment shows an example providing two nozzles spraying mixture to the semiconductor substrate 106. FIG. 14 is a view showing one example of the substrate treatment device 100 according to the present embodiment, and FIGS. 15A, 15B are views showing position relationship between nozzles 112a, 112b shown in FIG. 14 and the semiconductor substrate 106. Device structure of the present embodiment is the same as the device structure indicated in the first embodiment other than the nozzle structure. The point arranging the heater around the piping 115 and the nozzles 112 is the same as that indicated in the first embodiment.

As shown in FIGS. 15A, 15B the nozzle 112a sprays the mixture to the end part of the semiconductor substrate 106, and the nozzle 112b sprays the mixture to the center part of the semiconductor substrate 106. The nozzles are prepared at the angle “a” to the substrate surface and at the angle “b” to the direction of the substrate tangent.

In the present embodiment, in addition to the effect described in the first embodiment, following effect is demonstrated.

The device according to the present embodiment is provided with two nozzles of the nozzle 112a and the nozzle 112b. The constitution is that one sprays the treatment liquid to the center part of the semiconductor substrate 106 and the other sprays the treatment liquid to the end part of the semiconductor substrate 106. Owing to this, the temperature becomes even in treatment surface of the semiconductor substrate 106, as a result, resist stripping efficiency becomes even. Although the present embodiment is one in which the treatment liquid is made high temperature while utilizing heat generated by mixing of two liquids, in such a case, in the surface of the semiconductor substrate 106, difference of temperature distribution easily takes place between a place to which the liquid strikes directly, and a place to which the liquid does not strike. Consequently, it is possible to improve stability of the treatment in such a way that plural nozzles are made prepared as above, followed by constituting the method so as to strike the liquid to different positions of the semiconductor substrate 106.

### Third Embodiment

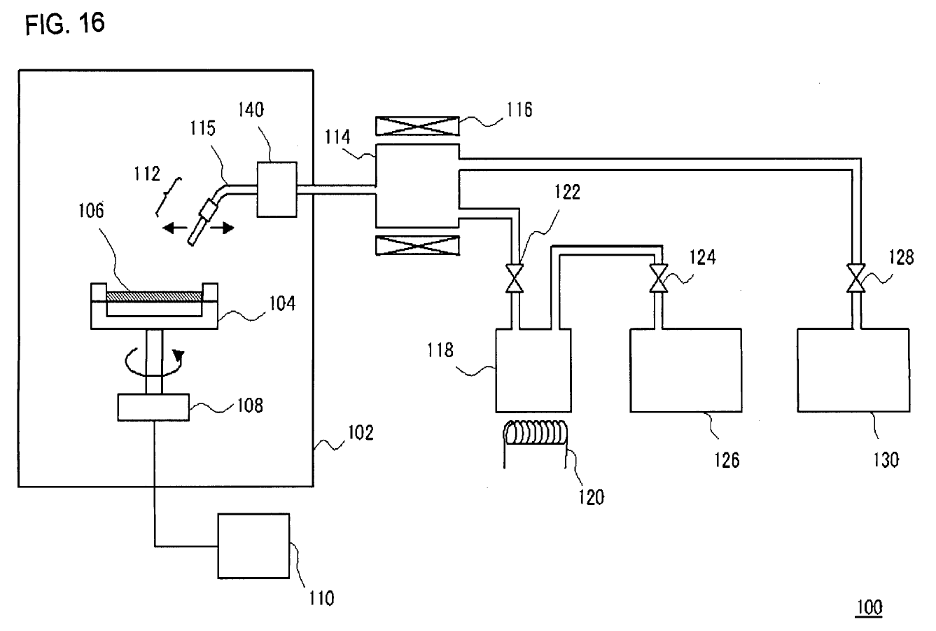

In the present embodiment, indicated is an example in which the mixture is made to spray to the semiconductor substrate 106. FIG. 16 is a view showing one example of the substrate treatment device 100 according to the present embodiment. Device structure of the present embodiment is the same as the device structure indicated in the first embodiment other than the nozzle structure. The point arranging the heater around the piping 115 and the nozzles 112 shown in FIG. 17 is the same as that indicated in the first embodiment. As shown in the drawing, in this device, the nozzle 112 becomes movable because of control of a moving part 140. The nozzle 112 is constituted so as to spray the mixture while moving a sprayed portion from substrate center to periphery part. In such a constitution as above, within treatment surface of the semiconductor substrate 106, temperature becomes even, as a result, resist stripping efficiency becomes even. Although the present embodiment is one in which the treatment liquid is made high temperature while utilizing heat generated by mixing of two liquids, in such a case, in the surface of the semiconductor substrate 106, difference of temperature distribution easily takes place between a place to which the liquid strikes directly, and a place to which the liquid does not strike. Consequently, as described above, the treatment is made to carry out while moving sprayed potion of the liquid, owing to this, it is possible to improve stability of the treatment.

### Fourth Embodiment

Performed is a rinse process by the method of following two systems, while using the device indicated in the above embodiment, after carrying out resist peeling treatment by SPM.
(i) Pure water rinse treatment
(ii) Pure water rinse treatment, after rinsing by means of dilution ammonia water

Rinse treatment by the system (ii) to completion takes shorter time than rinse treatment by the system (i) to completion.

It should be noted that there has been obtained the same tendency as that also dilution APM (ammonia hydrogen peroxide water) or alkali reduced water is used instead of the system (ii).

As above, there is described the preferred embodiment of the present invention, while taking example of treatment stripping the resist.

Here, particularly, resist remaining has a tendency to be easily generated at the peripheral end of the wafer. As its reason, following matter is guessed.

The first reason is that difference of temperature distribution easily takes place within wafer surface. Peripheral end of the wafer easily changes into low temperature in comparison with the center part of the wafer, as a result, it is conceivable that, in the peripheral end of the wafer, resist stripping efficiency deteriorates.

The second reason is that the resist hardening layer firmly adheres to the peripheral end of the wafer. Generally, resist is formed such that film thickness is thinning gradually from the center part of the wafer toward the peripheral end. That is, film thickness of the resist is formed in such a way as to be thick in the center part and thin in the peripheral end. In the center part of the wafer, upper part of the resist becomes the resist hardening layer, when the resist hardening layer is stripped, resist of its lower part is easily stripped by lift-off action. On the other hand, in the peripheral end of the wafer, thickness of the resist is thin, therefore, approximately whole resist deteriorates to the hardening layer, consequently, it can not be expected that the resist is stripped caused by lift-off action as the center part of the wafer. For that reason, compared with the center part of the wafer, in the peripheral end of the wafer, removal of the resist hardening layer becomes difficult.

The third reason is that the treatment liquid is difficult to be maintained on the surface of the peripheral end of the wafer. In the peripheral end of the wafer, slip of the treatment liquid is easy to take place, as a result, treatment efficiency deteriorates.

In this respect, in the present embodiment, following measures are taken, to effectively resolve the resist remaining at the peripheral end of the wafer.

As a measure to the matter described in the above first reason, in the embodiment, upon providing the mixing part 114, and the mixture (SPM) is made to adjust immediately before supplying to the semiconductor substrate 106 to control temperature. For this reason, it is possible to make temperature distribution within the surface of the wafer even. If adopting constitution provided with a plurality of nozzles 112 as the second embodiment, or constitution provided with a movable nozzle as the third embodiment, evenness of the temperature further improves.

Further, with respect to the matters described in the above second and the third reasons, in the above embodiment, the rotation controller 110 appropriately controls the number of revolution of the substrate, owing to this, the slip of treatment liquid in the peripheral end of the wafer is made to suppress and stripping efficiency of the resist hardening layer is made to enhance. For instance, after treating with relatively high speed revolution, carried out is the treatment with low speed revolution where the slip of the treatment liquid is difficult to take place and the treatment liquid is easy to be maintained at the peripheral end of the wafer.

For these reasons, in the embodiment, the resist remaining at the peripheral end of the wafer is made to effectively solve.

As above, there has been described the embodiment of the present invention with reference to the drawings, however, these are illustrations of the present invention, consequently, it is possible to adopt various constitutions other than the above descriptions.

For instance, in the above described embodiments, the SPM is used as the treatment liquid, if matter is capable of sufficiently stripping the resist pattern after dry etching with the single-wafer system treatment, it is possible to use the matter other than the SPM. As the resist stripping liquid described above, for instance, a solvent mainly comprising phenol and halogen-based solvent, amine-based solvent, and ketone-based solvent such as cyclopentanone or methyl ethyl ketone are indicated. Provided the resist after dry etching is modified in connection with its surface, so that, generally, solubility to the solvent is low in comparison with the resist before dry etching, and the resist residue is easy to remain, consequently, it is preferable to perform SPM cleaning with high resist peeling effect. The composition of SPM can be set to be the sulfuric acid: 30 mass % oxygenated water=1:1 to 8:1 (volume factor), and the working temperature is capable of being set within the range of 100 to 150° C. By this measure, preferable stripping performance and cleaning efficiency can be obtained stably.

Further, in the above embodiment, which takes treatment of the silicon substrate as an example, however, various semiconductor substrates such as semiconductor and the like including elements of Si, Ge or the like are possible to be made application objects. Among them, in the case where the semiconductor substrate is taken to as silicon wafer, effect of the present invention is further remarkably exhibited.

In the above embodiments, peeling treatment of the resist is taken to as an example, however, “treatment” in the present invention includes the whole treatment of substrate surface using chemical liquid or its vapor. For instance, included is wet etching treatment, stripping treatment stripping etching residue, or the like.

### EXAMPLE

### Example 1

SiGe gate pattern is formed as being transistor forming gate length to be not less than 100 nm, on the silicon wafer in accordance with the above described method through the lithography technique and the dry etching technique. The gate pattern has a section whose width is not more than 150 nm and height to the width is not less than 1.

In order to remove the resist pattern, which has become unnecessary after dry etching, performed is SPM cleaning based upon following condition while using the single-wafer system cleaning device shown in FIG. 1. Successively, performed through using the same single-wafer system cleaning device, by carrying out the rinse treatment using the pure water, is drying treatment.

Provided SPM composition: sulfuric acid/30 wt % oxygenated water=1/1 (volume factor), SPM delivery amount to wafer surface: 100 to 200 ml, SPM temperature: 100° C., SPM treatment time: two seconds.

### Comparison Example 1

Like the Example 1, prepared is a wafer on which SiGe gate pattern is formed. In order to remove the resist pattern, which has become unnecessary after dry etching, performed is SPM cleaning based upon following condition while using the dip type system using quartz tank. Successively, performed is drying treatment after performing rinse treatment with the pure water based on the dip system while using different quartz tank.

Provided SPM composition: sulfuric acid/30 wt % oxygenated water=5/1 (volume factor), treatment tank: quartz tank of volume 45 L, the number of wafer for treatment by one batch: 50, SPM temperature: 140° C., SPM treatment time: ten seconds.

[Evaluation of the Number of Particle Adhesion]

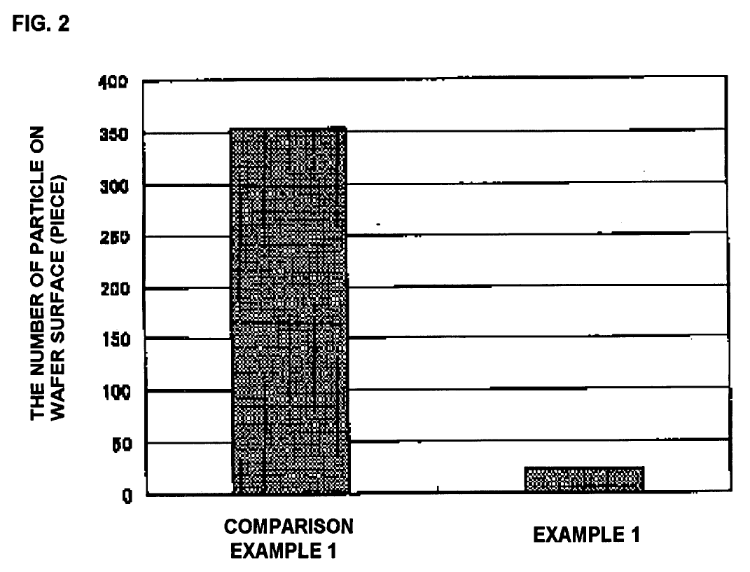

Performed is measurement of the number of particle adhering to wafer surface of the wafer, in which treatment is in the Example 1 and the comparison example 1, while using the wafer fault inspecting device (KLA-Tencor Company 2351). Result is indicated in FIG. 2.

[Evaluation of Metal Adhesion]

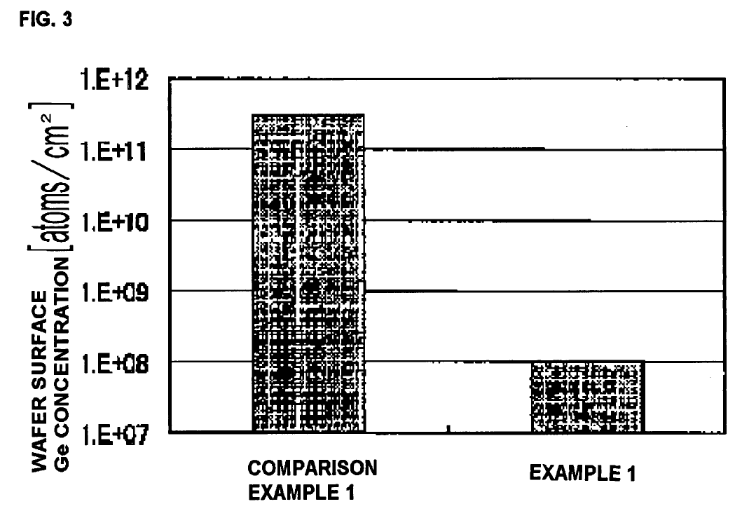

Performed is measurement of Ge amount adhering to wafer surface of the wafer, in which treatment is in the Example land the comparison example 1, while using the commercially available wafer surface inspecting device (total reflection type X-ray fluorescence analyzer). Result is indicated in FIG. 3. It should be noted that about the comparison example 1, measured is Ge adhesion of the wafer surface after wafer treatment of 1000 sheets.

[Evaluation of the Number of Generation of Pattern Peeling]

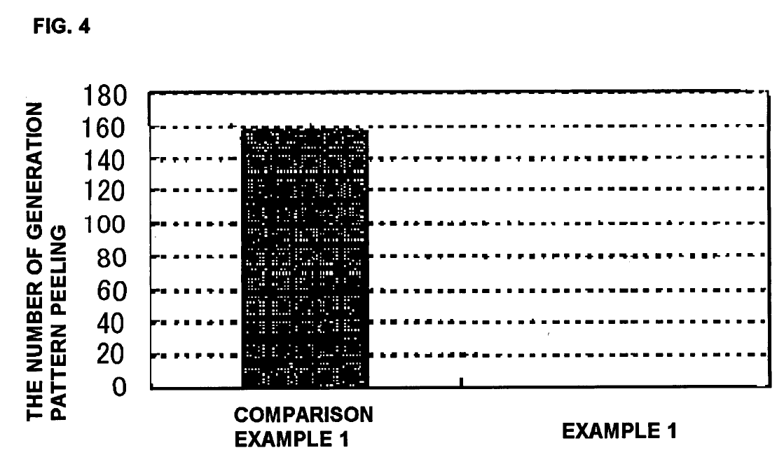

Performed is measurement of the number of pattern peeling generation, in which treatment is in the Example 1 and the comparison example 1, while using the wafer fault inspecting device (KLA-Tencor Company 2351). Result is indicated in FIG. 4. The pattern peeling is not observed on the wafer of the Example 1. It should be noted that, about the comparison example 1, indicated is result of the case adding Megasonic, in the rinse treatment of frequency 950 kHz, output 120 W during 10 minutes.

As clear from the above evaluated results, according to the present invention, it is possible to sufficiently suppress particle of the wafer surface or adhesion of the metal impurities without damaging fine pattern.

### Example 2

In the present embodiment, indicated is an example of a method for manufacturing the semiconductor device including:
(1) a process of forming resist pattern on the upper part of the semiconductor substrate,
(ii) a process of performing treatment to an exposed region with a resist pattern as a mask,
(iii) a process of stripping resist pattern upon supplying rest stripping liquid to resist pattern forming surface of the semiconductor substrate in the condition that the semiconductor substrate is made to horizontally maintain to rotate.

Specifically, a process (ii) is a process forming a SiGe gate pattern while carrying out dry etching of the polysilicon into which impurities are introduced.

Process of stripping resist pattern of the process (iii) comprises:
a first step supplying resist stripping liquid to a resist pattern forming surface while relatively rotating the semiconductor substrate in high speed, and
a second step supplying resist stripping liquid to a resist pattern forming surface while relatively rotating the semiconductor substrate in low speed, after the first step.

Hereinafter, there will be described specifically.

First, formed on the silicon wafer is a SiGe gate pattern whose gate length is not more than 100 nm. After that, impurities making short-channel effect inhibition an object are made to perform ion implantation with the resist pattern as a mask separately to respective N-MOS region, and P-MOS region. In each ion implantation process, dose amount is taken to be not less than 10¹⁴ cm⁻².

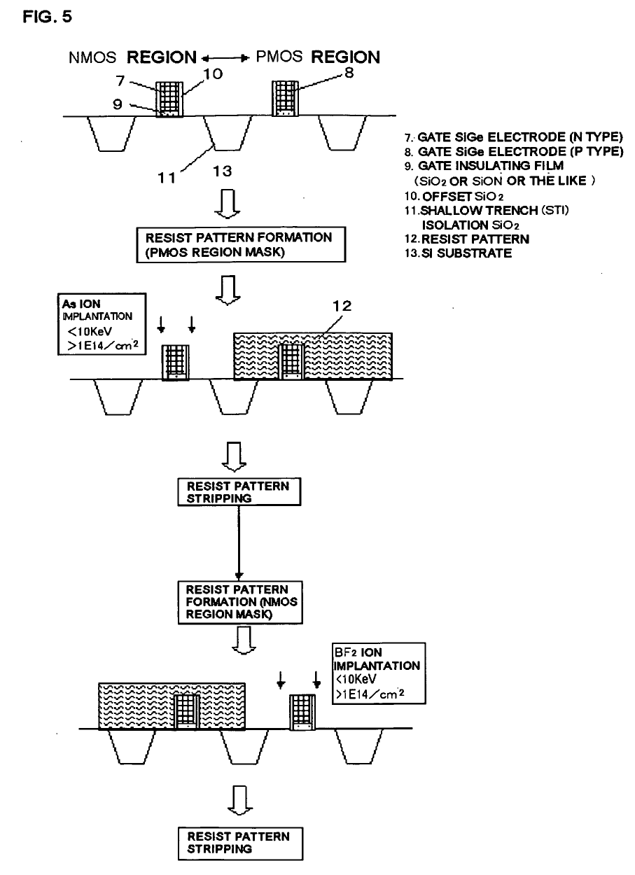

Process flow is just shown in FIG. 5. Here, in the process stripping unnecessary resist pattern after ion implantation, performed is SPM cleaning with sequence shown in FIG. 6 while using the single-wafer system cleaning device shown in FIG. 1. That is, performed is the cleaning composed of the first step supplying resist liquid under condition of high speed revolution, and the second step supplying resist liquid under condition of low speed revolution. When performing impurity introducing of high dose-rate as the present embodiment, resist hardening layer is generated within resist pattern. It is possible to effectively strip this resist hardening layer with the above described second step.

It should be noted that, although it is not shown in the drawings, SPM temperature, composition, pure water rinse, and drying processes are the same as those of the Example 1. Further, after the present flow, side wall oxide film formation and source drain implantation are performed, so that transistor is formed.

### Comparison Example 2

After ion implantation of the Example 2, process of stripping resist pattern is performed with the dip system shown in the comparison example 1.

[Evaluation of the Number of Defect After Resist Pattern Stripping]

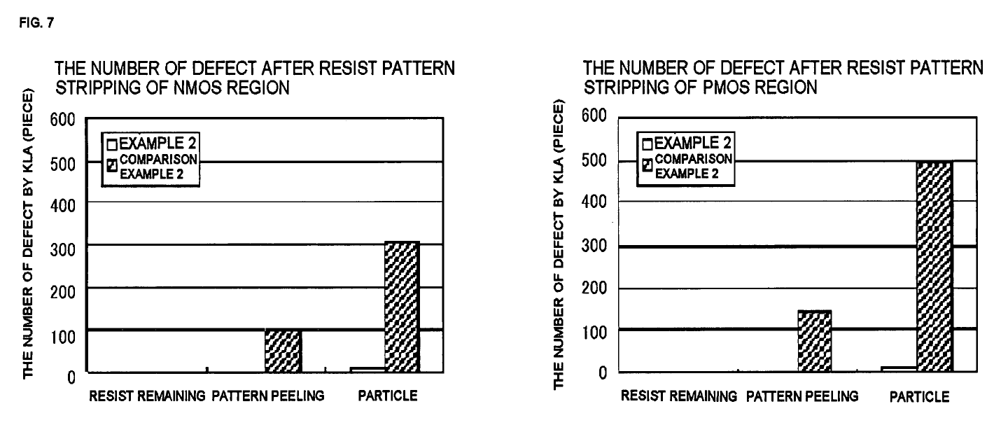

Like the Example 1, evaluated is the number of defect after resist pattern stripping while using KLA. Result is indicated in FIG. 7.

Resist remaining is not generated in both the Example 2 and the comparison example 2, however, in the comparison example 2, pattern peeling or particle are generated. The pattern peeling is generated caused by damage due to Megasonic.

In the Example 2 using single-wafer cleaning to the comparison example 2, there is no damage because Megasonic is not used, and pattern peeling is not generated entirely, further the number of generation of particle, because of no backside transfer, is suppressed into very a few number of particles.

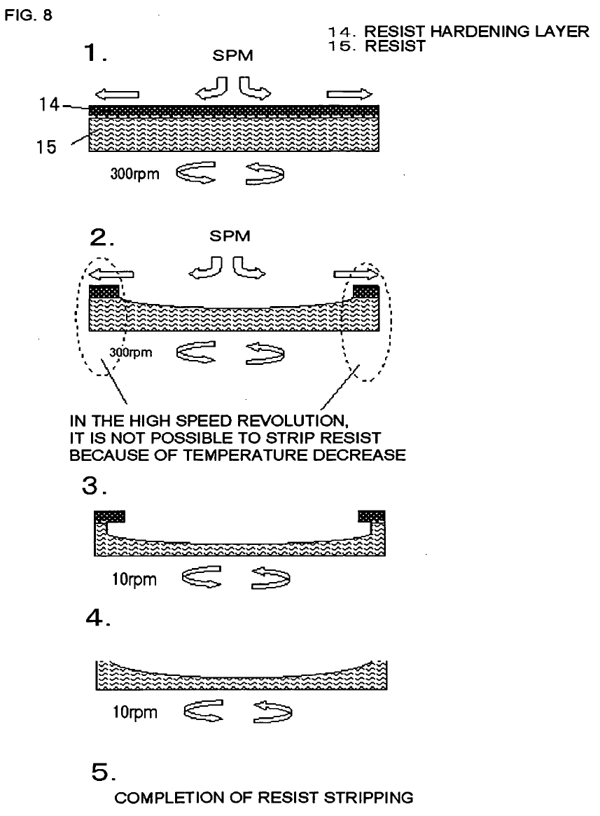

Further, amount of ion implantation, which is not less than 1E14/cm² is relatively large, despite the hardening layer is formed on the resist surface, it is possible to sufficiently strip the resist by only the single-wafer cleaning of the Example 2. This is caused by the fact that sequence is made to contrive to arrange the steps as FIG. 6. That is, first, in order to strip the hardening layer, the SPM liquid is made to deliver continuously during a period of 9 seconds while rotating the wafer in high speed revolution. In this high speed revolution step, the number of contact between the wafer and the SPM liquid increases, owing to this, removal of the hardening layer substantially progresses. After that, the number of revolution decreases into low speed, and after delivering the SPM liquid during a period of 10 seconds, delivery is made to stop for chemical liquid saving, protuberant liquid of the SPM liquid at the center part of the wafer is spread to peripheral part of the wafer by centrifugal force, relatively soft resist layer beneath the hardening layer is stripped (paddling). A little remaining hardening layer in the periphery at this time is stripped by the lift-off. It should be noted that when high speed revolution continues and there is no paddling, liquid temperature lowering takes place at peripheral part of the wafer resulting in generation of separation residue. Consequently, in the resist stripping of the case where, as the present embodiment, the hardening layer caused by the ion implantation resides on the surface, the present sequence is effective. Indicated is the resist stripping process in FIGS. 8(1 to 5) as being schematic view.

### Example 3

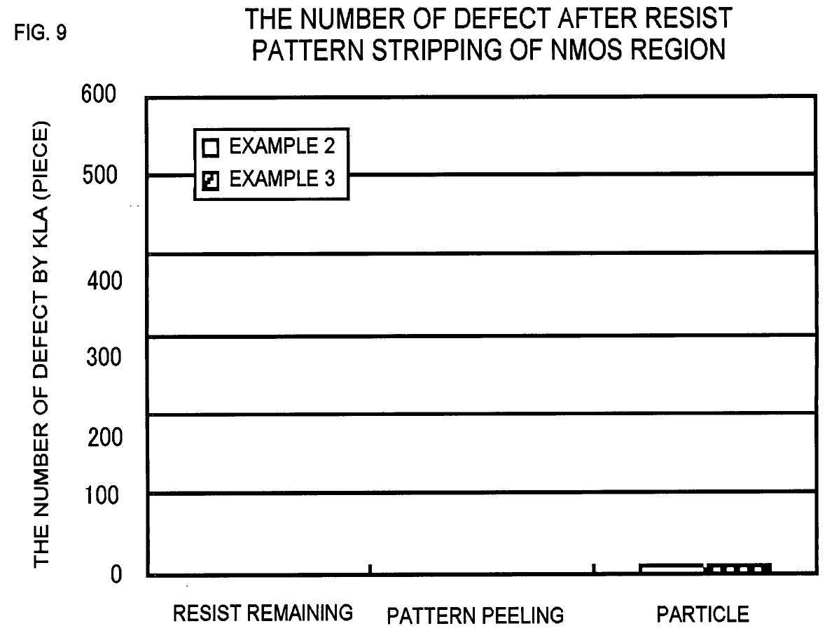

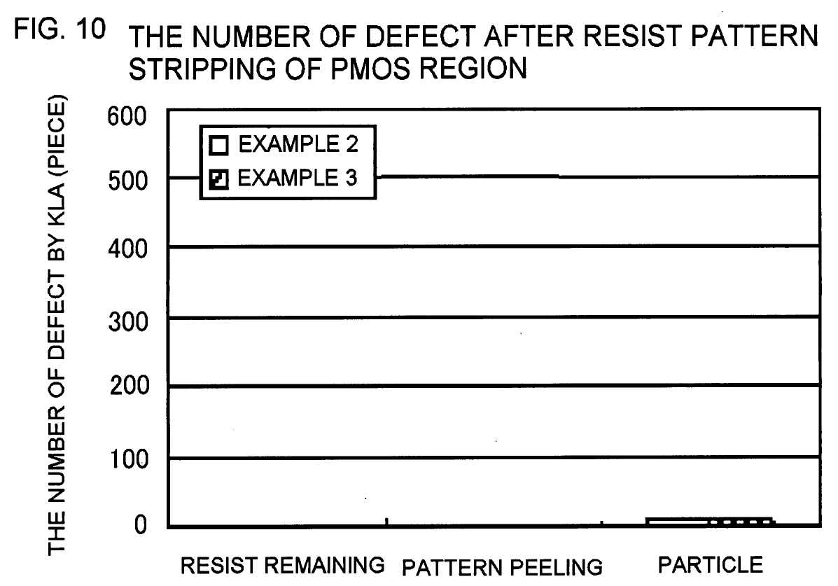

In the Example 2, liquid supply is not H₂SO₄+H₂O₂, but H₂SO₄+Caro's acid (H₂SO₅). The resist stripping by SPM is achieved in such a principle that Caro's acid (H₂SO₅) generated by mixing H₂SO₄ with H₂O₂ has strong oxidizing force, and the resist is subjected to oxidative decomposition by Caro's acid. Consequently, even though H₂SO₄ compounded by Caro's acid is used, the same effect as the SPM as being H₂SO₄+H₂O₂ can be obtained. In this respect, it is possible to simplify liquid supply mechanism, because of single supply constitution. Performed is the same evaluation of the Example 2 with H₂SO₄ compounded by this Caro's acid, it has been ascertained that entirely the same result can be obtained (FIG. 9, FIG. 10).

It is apparent that the present invention is not limited to the above embodiment, that modified and changed without departing from the scope and sprit of the invention.

1. A method for manufacturing a semiconductor device, comprising:
forming a resist pattern, on an upper part of a semiconductor substrate;
performing treatment with said resist pattern as a mask; and
stripping said resist pattern while supplying resist stripping liquid to a resist pattern forming surface of said semiconductor substrate in a condition that said semiconductor substrate is made to rotate with said semiconductor substrate horizontally maintained,
wherein the step of stripping resist pattern, comprising:
supplying said resist stripping liquid to said resist pattern forming surface while rotating said semiconductor substrate in relatively high speed as a first step; and
supplying said resist stripping liquid to said resist pattern forming surface while rotating said semiconductor substrate in relatively low speed as a second step after said first step.

2. The method for manufacturing the semiconductor device, according to claim 1, wherein, in the step of performing treatment, ion plantation is made to carry out to a whole surface of the substrate with the resist pattern as the mask.

3. The method for manufacturing the semiconductor device according to claim 2, wherein dose amount in said ion implantation is not less than 10¹⁴ cm⁻², and a resist hardening layer generated in a resist pattern caused by said ion plantation is made to strip by way of said second step.

4. The method for manufacturing the semiconductor device according to claim 1, further comprising:
forming said resist pattern on a film provided on said semiconductor substrate; and
forming a fine pattern of said film, in the step of performing treatment, upon selectively performing dry etching of the conductive film with said resist pattern as the mask.

5. The method for manufacturing the semiconductor device according to claim 4, wherein said fine pattern has part whose width is not more than 150 nm.

6. The method for manufacturing the semiconductor device according to claim 4, wherein said fine pattern has part whose width is not more than 150 nm and whose height to its width is not less than 1.

7. The method for manufacturing the semiconductor device according to claim 4, wherein said fine pattern is a gate pattern.

8. The method for manufacturing the semiconductor device according to claim 7, wherein, said gate pattern is SiGe gate pattern having SiGe layer containing Si and Ge.

9. The method for manufacturing the semiconductor device according to claim 7, wherein said gate pattern is polycrystalline or amorphous silicon gate pattern.

10. The method for manufacturing the semiconductor device according to claim 7, wherein said fine pattern is a metal gate pattern.

11. The method for manufacturing the semiconductor device according to claim 1, wherein liquid including Caro's acid is made to use as said resist stripping liquid.

12. The method for manufacturing the semiconductor device according to claim 1, wherein said resist stripping liquid is organic solvent.

13. The method for manufacturing the semiconductor device according to claim 1, wherein first liquid containing acid and second liquid containing hydrogen peroxide are made mix within airtight space, obtained mixture is taken to as said resist stripping liquid, and said resist stripping liquid is made to supply to said resist pattern forming surface via a nozzle.

14. The method for manufacturing the semiconductor device according to claim 13, wherein said first liquid or said second liquid is heated into predetermined temperature previously.

15. The method for manufacturing the semiconductor device according to claim 13, wherein said first liquid is sulfuric acid and said second liquid is oxygenated water.

16. The method for manufacturing the semiconductor device according to claim 1, wherein, before said first step, process to provide sulfuric acid to the resist pattern forming surface of said semiconductor substrate is included.

17. The method for manufacturing the semiconductor device according to claim 1, wherein said resist stripping liquid is made to supply to said resist pattern forming surface via a plurality of nozzles.

18. The method for manufacturing the semiconductor device according to claim 1, wherein said resist stripping liquid is previously heated into predetermined temperature, thereafter, said resist stripping liquid is made to supply to said resist pattern forming surface.

19. The method for manufacturing the semiconductor device according to claim 1, further comprising:
performing rinse treatment of said semiconductor substrate after the step of stripping said resist pattern;
performing the rinse treatment, in the step of performing rinse treatment, while supplying rinse liquid on the semiconductor substrate; and
drying the semiconductor substrate maintained to said maintaining unit in such a way as to rotate the semiconductor substrate by said rotating unit.

20. The method for manufacturing the semiconductor device according to claim 19, wherein said rinse liquid is an alkali liquid, an electrolytic cathode water, or a water with dissolved hydrogen gas.

21. The method for manufacturing the semiconductor device according to claim 19, further comprising:
cleaning said semiconductor substrate from which the resist pattern is stripped with hydrofluoric acid; and
cleaning said semiconductor substrate already being subjected to cleaning by the hydrofluoric acid, with mixture of ammonia water and oxygenated water.

22. A resist stripping cleaning device having a treatment chamber for a single-wafer system, comprising:
a maintaining unit maintaining a semiconductor substrate;
a rotating unit rotating the semiconductor substrate maintained by said maintaining unit;
a cleaning liquid supplying unit supplying a resist stripping liquid on the semiconductor substrate maintained by said maintaining unit; and
a rinse liquid supplying unit supplying the rinse liquid on the semiconductor substrate maintained by said maintaining unit.

23. A resist stripping cleaning device having a first treatment chamber for a single-wafer system and a second treatment chamber for a single-wafer system, wherein
said first treatment chamber for a single-wafer system comprising:
a maintaining unit maintaining a semiconductor substrate;
a rotating unit rotating the semiconductor substrate maintained by said maintaining unit;
a cleaning liquid supplying unit supplying an acid resist stripping liquid on the semiconductor substrate maintained by said maintaining unit; and
a rinse liquid supplying unit supplying the rinse liquid on the semiconductor substrate maintained by said maintaining unit, and
said second treatment chamber for a single-wafer system comprising:
a maintaining unit maintaining a semiconductor substrate;
a rotating unit rotating the semiconductor substrate maintained by said maintaining unit;
a cleaning liquid supplying unit supplying an alkali resist stripping liquid on the semiconductor substrate maintained by said maintaining unit; and
a rinse liquid supplying unit supplying the rinse liquid on the semiconductor substrate maintained by said maintaining unit.

24. The resist stripping cleaning device according to claim 22, further comprising:
A heating unit heating the resist stripping liquid; and
A thermally insulating unit thermally insulating heated resist stripping liquid.

25. The resist stripping cleaning device according to claim 23, further comprising:
A heating unit heating the resist stripping liquid; and
A thermally insulating unit thermally insulating heated resist stripping liquid.
